(19) United States
(12) Patent Application Publication
(10) Pub. No.: US 2024/0419879 A1
(43) Pub. Date: Dec. 19, 2024

(54) CLOCK GATING SYSTEM AND METHOD FOR PROTECTING HARDWARE DESIGNS

(71) Applicant: University of Florida Research Foundation, Incorporated, Gainesville, FL (US)

(72) Inventors: Mark M. Tehranipoor, Gainesville, FL (US); Farimah Farahmandi, Gainesville, FL (US); Hadi Mardani Kamali, Gainesville, FL (US); Mohammad Rahman, Gainesville, FL (US); Rui Guo, Gainesville, FL (US); Fahim Rahman, Gainesville, FL (US)

(21) Appl. No.: 18/734,443

(22) Filed: Jun. 5, 2024

Related U.S. Application Data
(60) Provisional application No. 63/508,632, filed on Jun. 16, 2023.

(51) Int. Cl. G06F 30/327

(52) U.S. Cl. CPC G06F 30/327

(57) ABSTRACT

A method and system are directed to protecting hardware intellectual property (IP) of hardware designs. The method comprises receiving a hardware locking request comprising a register transfer level (RTL) design file, generating a circuit representation of the RTL design file, wherein the circuit representation comprises a translation of the RTL design file into one or more logic elements. The method may further comprise inserting a plurality of key programmable integrated clock gates (ICGs) into the circuit representation and generating a clock gated and locked netlist based on the insertion of the plurality of key programmable ICGs into the circuit representation.

### CROSS REFERENCE TO RELATED APPLICATION

This application claims the priority of U.S. Provisional Application No. 63/508,632, entitled “CLOCK GATING SYSTEM AND METHOD FOR PROTECTING HARDWARE DESIGNS,” filed on Jun. 16, 2023, the disclosure of which is hereby incorporated by reference in its entirety.

### TECHNICAL FIELD

Various embodiments of the present disclosure relate to logic locking, and more particularly to clock gate locking for protecting hardware against deobfuscation attacks.

### BACKGROUND

Cost increases from integrated circuit (IC) manufacturing processes, shrinking technology nodes, and growing complexity of integrated circuits have forced original equipment manufacturers (OEMs) to outsource parts of their design, integration, and fabrication processes to overseas contract foundries and third-party entities. Such a shift to a horizontal IC supply chain model involving multiple entities worldwide has given rise to several security threats, including, but not limited to, intellectual property (IP) piracy, hardware Trojan insertion, counterfeiting, and overproduction. As passive countermeasures such as patents, copyrights, and watermarking fail to thwart these security threats, some existing techniques have focused on active design-for-trust (DfTr) strategies. Amongst them, logic locking has emerged as a proactive solution for concealing functionality of IP/IC by inserting additional gates (known as key gates). A trusted facility may configure key inputs, e.g., driven from an on-chip tamper-proof memory, after manufacturing, such that a design may only function when correct unlocking key input values are available during operation.

Combinational logic locking techniques, including random placement, maximum output corruption, interference-based, and sequential logic locking, have been challenged by the introduction of Boolean satisfiability (SAT)-based attacks. However, to increase the robustness against a SAT attack, different forms of SAT-resistant logic locking countermeasures exist, including, but not limited to, point-function, and routing-based locking. However, these techniques suffer from their own critical limitations. For instance, bypass and removal may allow an adversary to circumvent the effectiveness of point-function countermeasures. Similarly, a design-for-testability (DFT) infrastructure (e.g., a scan chain) may be restricted to access but is not secure against removal attacks. Additionally, sequential locking countermeasures include concealment of data flow or phase of a circuit by replacement of synchronous flip-flops with key-controllable asynchronous latches. However, due to the lack of full electronic design automation (EDA) tool support for asynchronous designs, replacing flip-flops with latches and implementing asynchronous latch-based designs raise burdensome challenges in the IC design process, and thus, rendering the usage of asynchronicity almost impractical for complex system-on-chips (SoCs).

### BRIEF SUMMARY

Various embodiments described herein relate to methods, apparatuses, and systems for protecting intellectual property (IP) of hardware designs. The disclosed embodiments may employ clock gating techniques and target clock gating enabling circuitry for obfuscation purposes.

In some embodiments, a method comprises receiving a hardware locking request comprising a register transfer level (RTL) design file; generating a circuit representation of the RTL design file, wherein the circuit representation comprises a translation of the RTL design file into one or more logic elements; inserting a plurality of key programmable integrated clock gates (ICGs) into the circuit representation; and generating a clock gated and locked netlist based on the insertion of the plurality of key programmable ICGs into the circuit representation.

In some embodiments, inserting the plurality of key programmable ICGs into the circuit representation further comprises determining one or more ICG parameters; inserting a plurality of synthesis-based key programmable ICGs into the circuit representation based on the one or more ICG parameters and a synthesis-based key; performing ICG locking prioritization analysis of a plurality of sub-circuits that are associated with the plurality of synthesis-based key programmable ICGs; locking one or more of the plurality of synthesis-based key programmable ICGs with the synthesis-based key based on the ICG locking prioritization analysis; and inserting one or more intent-based decoy ICGs into the circuit representation. In some embodiments, the one or more ICG parameters comprise minimum bit width or maximum fanout of gated clock trees. In some embodiments, the method further comprises determining the one or more ICG parameters based on a 2-tuple key size comprising the synthesis-based key and an intent-based key. In some embodiments, inserting the plurality of synthesis-based key programmable ICGs into the circuit representation further comprises clock gating the one or more logic elements by attaching a ICG cell to the one or more logic elements via a synthesis tool. In some embodiments, the method further comprises determining an amount of the plurality of synthesis-based key programmable ICGs to insert into the circuit representation based on a size of the synthesis-based key. In some embodiments, the ICG locking prioritization analysis comprises a fanout analysis or a domination feature analysis. In some embodiments, the fanout analysis comprises prioritizing fanout sub-circuitry based on narrowness or shallowness of depth. In some embodiments, the domination feature analysis comprises selecting most significant clock gated logic elements over least significant clock gated logic elements. In some embodiments, the one or more intent-based decoy ICGs comprise gating-based stripped functionality.

In some embodiments, a computing system comprises memory and one or more processors communicatively coupled to the memory. In some embodiments, the one or more processors are configured to receive a hardware locking request comprising a register transfer level (RTL) design file; generate a circuit representation of the RTL design file, the circuit representation comprising a translation of the RTL design file into one or more logic elements; insert a plurality of key programmable integrated clock gates (ICGs) into the circuit representation; and generate a clock gated and locked netlist based on the insertion of the plurality of key programmable ICGs into the circuit representation.

In some embodiments, the one or more processors are further configured to determine one or more ICG parameters; insert a plurality of synthesis-based key programmable ICGs into the circuit representation based on the one or more ICG parameters and a synthesis-based key; perform ICG locking prioritization analysis of a plurality of sub-circuits that are associated with the plurality of synthesis-based key programmable ICGs; lock one or more of the plurality of synthesis-based key programmable ICGs with the synthesis-based key based on the ICG locking prioritization analysis; and insert one or more intent-based decoy ICGs into the circuit representation. In some embodiments, the one or more ICG parameters comprise minimum bit width or maximum fanout of gated clock trees. In some embodiments, the one or more processors are further configured to determine the one or more ICG parameters based on a 2-tuple key size comprising the synthesis-based key and an intent-based key. In some embodiments, the one or more processors are further configured to clock gate the one or more logic elements by attaching a ICG cell to the one or more logic elements via a synthesis tool. In some embodiments, the one or more processors are further configured to determine an amount of the plurality of synthesis-based key programmable ICGs to insert into the circuit representation based on a size of the synthesis-based key. In some embodiments, the ICG locking prioritization analysis comprises a fanout analysis or a domination feature analysis. In some embodiments, the domination feature analysis comprises selecting most significant clock gated logic elements over least significant clock gated logic elements. In some embodiments, the fanout analysis comprises prioritizing fanout sub-circuitry based on narrowness or shallowness of depth.

In some embodiments, one or more non-transitory computer-readable storage media includes instructions that, when executed by one or more processors, cause the one or more processors to receive a hardware locking request comprising a register transfer level (RTL) design file; generate a circuit representation of the RTL design file, the circuit representation comprising a translation of the RTL design file into one or more logic elements; insert a plurality of key programmable integrated clock gates (ICGs) into the circuit representation; and generate a clock gated and locked netlist based on the insertion of the plurality of key programmable ICGs into the circuit representation.

### BRIEF DESCRIPTION OF THE DRAWINGS

Embodiments incorporating teachings of the present disclosure are shown and described with respect to the figures presented herein.

FIG. 1 illustrates an example overview of an architecture that may be used to practice embodiments of the present disclosure.

FIG. 2 illustrates an example hardware locking computing entity in accordance with some embodiments discussed herein.

FIG. 3 illustrates an example client computing entity in accordance with some embodiments discussed herein.

FIG. 4 illustrates an example circuit that may be used to perform a Boolean satisfiability (SAT) attack.

FIG. 5 illustrates an example unrolling of a circuit in a sequential SAT attack.

FIG. 6 illustrates an example overview of system-on-chip-level clock gating.

FIG. 7A illustrates an example integrated clock gate (ICG) cell.

FIG. 7B illustrates an example ICG cell with locked enabler logic.

FIG. 8 is a flowchart diagram of an example process for protecting an integrated circuit design in accordance with some embodiments discussed herein.

FIG. 9 is a flowchart diagram of an example process for inserting key programmable ICGs into a hardware design and locking at least a portion thereof in accordance with some embodiments discussed herein.

FIGS. 10A, 10B, 10C, and 10D illustrate example fanout analysis of fanout sub-circuitries coupled to ICGs in accordance with some embodiments discussed herein.

FIG. 11 illustrates an example of domination feature analysis of a sub-circuit in accordance with some embodiments discussed herein.

FIG. 12 illustrates an example of domination feature analysis on the most significant bits (MSBs) of an arithmetic circuit in accordance with some embodiments discussed herein.

FIG. 13A illustrates an example sub-circuit modeled based on a finite-state machine.

FIG. 13B illustrates an example sub-circuit intent-based decoy clock gating in accordance with some embodiments discussed herein.

FIG. 14A and FIG. 14B illustrate example logic tables of an original sub-circuit and the sub-circuit with an intent-based decoy ICG, respectively, in accordance with some embodiments discussed herein.

### DETAILED DESCRIPTION

Various embodiments of the present disclosure now will be described more fully hereinafter with reference to the accompanying drawings, in which some, but not all embodiments of the disclosure are shown. Indeed, the disclosure may be embodied in many different forms and should not be construed as limited to the embodiments set forth herein. Rather, these embodiments are provided so that this disclosure will satisfy applicable legal requirements. The term “or” is used herein in both the alternative and conjunctive sense, unless otherwise indicated. The terms “illustrative,” “example,” and “exemplary” are used to be examples with no indication of quality level. Like numbers refer to like elements throughout.

### General Overview and Example Technical Improvements

The present disclosure provides a clock gate locking mechanism for safeguarding against different attacks on hardware intellectual property (IP) designs. Existing logic locking techniques may prevent IP piracy or tampering but often come at the expense of high overhead and are gradually becoming vulnerable to emerging deobfuscation attacks. As such, the present application discloses a clock gating-based system and method that “locks the clock” to protect IPs in complex integrated circuit (IC) designs, such as of system-on-chips (SoCs). According to some embodiments, data/control flows are obstructed and underlying logic are made dysfunctional for incorrect unlocking keys used to access logic-locked designs by manipulating activity factor of a clock tree. Embodiments of the present disclosure may comprise minimal changes to an original design and no change to IC design flow.

The disclosed embodiments of the present application provide high resiliency against state-of-the-art de-obfuscation attacks, such as oracle-guided Boolean satisfiability (SAT), unrolling-/bounded-model-checker (BMC)-based SAT, removal, and oracle-less machine learning-based attacks, at negligible power, performance, and area (PPA) overhead. The disclosed embodiments may also disrupt synchronous behavior, manipulate timing networks, alter timing paths delays, and influence output corruptibility. Also, unlike scan blockage-based SAT-resistant techniques, embodiments of the present disclosure may keep scan chain available (which may be imperative for performing in-field debug and test but exploitable by SAT attack) to an untrusted foundry and end-users while resisting SAT-based attacks. Embodiments of the present disclosure are also scalable from module to SoC-level and may be adopted in an industrial design flow with support from commercial electronic design automation (EDA) tools.

### Example Technical Implementation of Various Embodiments

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD), solid state card (SSC), solid state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FcRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described with reference to example operations, steps, processes, blocks, and/or the like. Thus, it should be understood that each operation, step, process, block, and/or the like may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some example embodiments, retrieval, loading, and/or execution may be performed in parallel such that multiple instructions are retrieved, loaded, and/or executed together. Thus, such embodiments may produce specifically configured machines performing the steps or operations specified in the block diagrams and flowchart illustrations. Accordingly, the block diagrams and flowchart illustrations support various combinations of embodiments for performing the specified instructions, operations, or steps.

### Example System Architecture

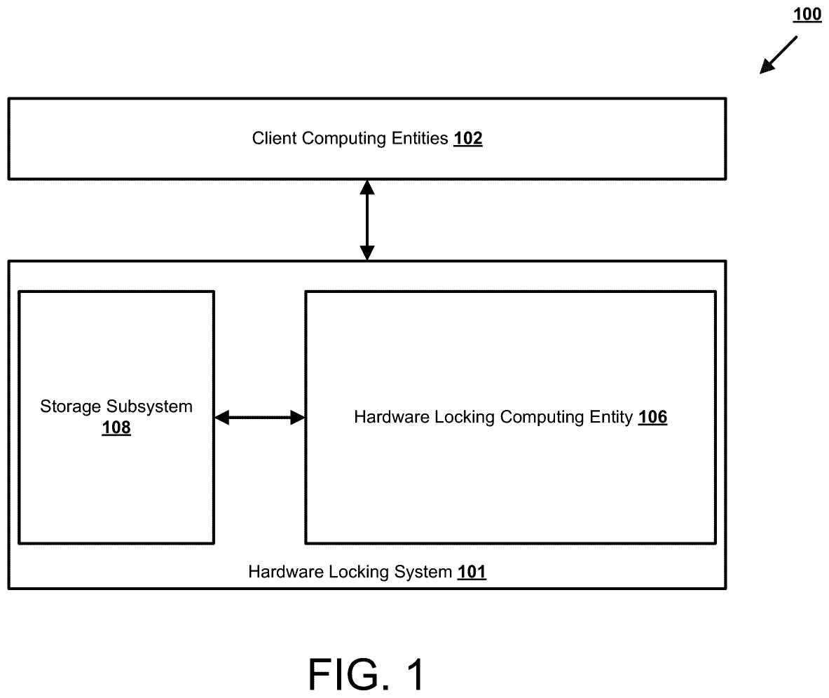

FIG. 1 is a schematic diagram of an example architecture 100 for securing hardware IP, such as SoCs. The architecture 100 includes a hardware locking system 101 configured to receive hardware locking requests from client computing entities 102, process the hardware locking requests to generate hardware locking modifications, and provide the generated hardware locking modifications to the client computing entities 102.

In some embodiments, hardware locking system 101 may communicate with at least one of the client computing entities 102 using one or more communication networks. Examples of communication networks include any wired or wireless communication network including, for example, a wired or wireless local area network (LAN), personal area network (PAN), metropolitan area network (MAN), wide area network (WAN), or the like, as well as any hardware, software and/or firmware required to implement it (such as, e.g., network routers, and/or the like).

The hardware locking system 101 may include a hardware locking computing entity 106 and a storage subsystem 108. The hardware locking computing entity 106 may be configured to receive hardware locking requests from one or more client computing entities 102, process the hardware locking requests to generate hardware locking modifications corresponding to the hardware locking requests, and provide the generated hardware locking modifications to the client computing entities 102.

The storage subsystem 108 may be configured to store input data used by the hardware locking computing entity 106 to perform hardware locking. The storage subsystem 108 may include one or more storage units, such as multiple distributed storage units that are connected through a computer network. Each storage unit in the storage subsystem 108 may store at least one of one or more data assets and/or one or more data about the computed properties of one or more data assets. Moreover, each storage unit in the storage subsystem 108 may include one or more non-volatile storage or memory media including, but not limited to, hard disks, ROM, PROM, EPROM, EEPROM, flash memory, MMCs, SD memory cards, Memory Sticks, CBRAM, PRAM, FcRAM, NVRAM, MRAM, RRAM, SONOS, FJG RAM, Millipede memory, racetrack memory, and/or the like.

### Example Hardware Locking Computing Entity

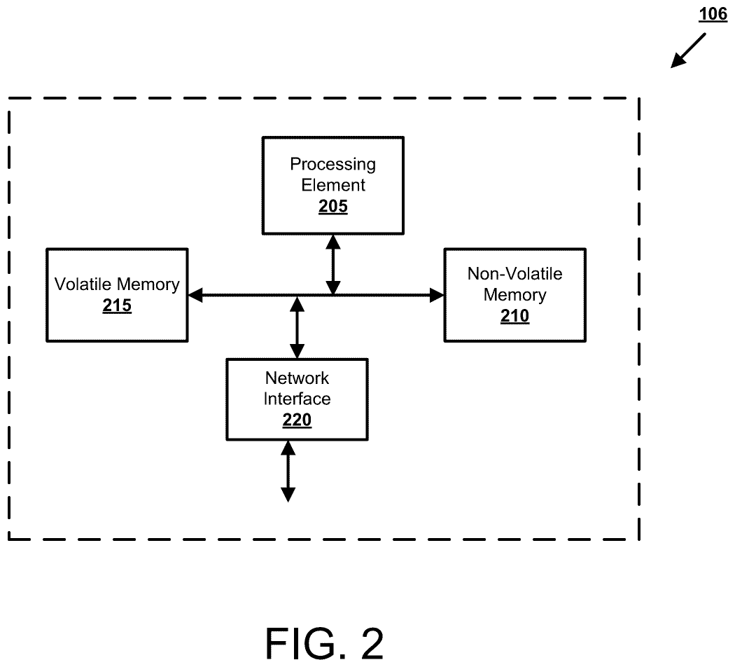

FIG. 2 provides a schematic of a hardware locking computing entity 106 according to one embodiment of the present disclosure. In general, the terms computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes may be performed on data, content, information, and/or similar terms used herein interchangeably.

As indicated, in one embodiment, the hardware locking computing entity 106 may also include one or more network interfaces 220 for communicating with various computing entities, such as by communicating data, content, information, and/or similar terms used herein interchangeably that may be transmitted, received, operated on, processed, displayed, stored, and/or the like.

As shown in FIG. 2, in one embodiment, the hardware locking computing entity 106 may include, or be in communication with, one or more processing elements 205 (also referred to as processors, processing circuitry, and/or similar terms used herein interchangeably) that communicate with other elements within the hardware locking computing entity 106 via a bus, for example. As will be understood, the one or more processing elements 205 may be embodied in a number of different ways.

For example, the one or more processing elements 205 may be embodied as one or more complex programmable logic devices (CPLDs), microprocessors, multi-core processors, coprocessing entities, application-specific instruction-set processors (ASIPs), microcontrollers, and/or controllers. Further, the processing element 205 may be embodied as one or more other processing devices or circuitry. The term circuitry may refer to an entirely hardware embodiment or a combination of hardware and computer program products. Thus, the processing element 205 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the one or more processing elements 205 may be configured for a particular use or configured to execute instructions stored in volatile or non-volatile media or otherwise accessible to the one or more processing elements 205. As such, whether configured by hardware or computer program products, or by a combination thereof, the one or more processing elements 205 may be capable of performing steps or operations according to embodiments of the present disclosure when configured accordingly.

In one embodiment, the hardware locking computing entity 106 may further include, or be in communication with, non-volatile media (also referred to as non-volatile storage, memory, memory storage, memory circuitry and/or similar terms used herein interchangeably). In one embodiment, the non-volatile storage or memory may include one or more non-volatile storage or memory media 210, including, but not limited to, hard disks, ROM, PROM, EPROM, EEPROM, flash memory, MMCs, SD memory cards, Memory Sticks, CBRAM, PRAM, FORAM, NVRAM, MRAM, RRAM, SONOS, FJG RAM, Millipede memory, racetrack memory, and/or the like.

As will be recognized, the non-volatile storage or memory media may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

In one embodiment, the hardware locking computing entity 106 may further include, or be in communication with, volatile media (also referred to as volatile storage, memory, memory storage, memory circuitry and/or similar terms used herein interchangeably). In one embodiment, the volatile storage or memory may also include one or more volatile storage or memory media 215, including, but not limited to, RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like.

As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the one or more processing elements 205. Thus, the databases, database instances, database management systems, data, applications, programs, program modules, scripts, source code, object code, byte code, compiled code, interpreted code, machine code, executable instructions, and/or the like may be used to control certain aspects of the operation of the hardware locking computing entity 106 with the assistance of the one or more processing elements 205 and operating system.

As indicated, in one embodiment, the hardware locking computing entity 106 may also include one or more network interfaces 220 for communicating with various computing entities, such as by communicating data, content, information, and/or similar terms used herein interchangeably that may be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the hardware locking computing entity 106 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1×(1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

Although not shown, the hardware locking computing entity 106 may include, or be in communication with, one or more input elements, such as a keyboard input, a mouse input, a touch screen/display input, motion input, movement input, audio input, pointing device input, joystick input, keypad input, and/or the like. The hardware locking computing entity 106 may also include, or be in communication with, one or more output elements (not shown), such as audio output, video output, screen/display output, motion output, movement output, and/or the like.

### Example Client Computing Entity

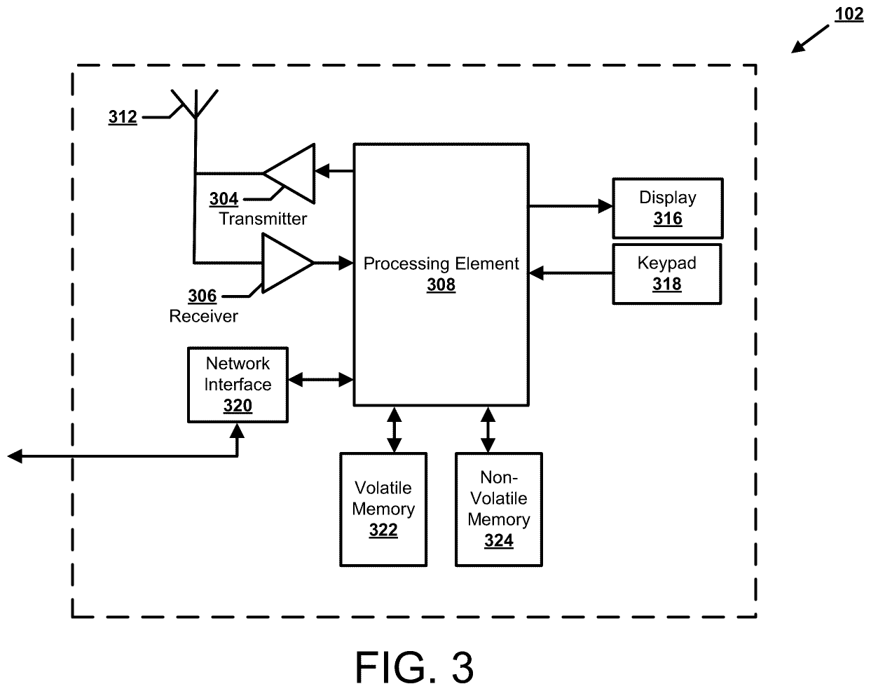

FIG. 3 provides an illustrative schematic representative of one of the client computing entities 102 that may be used in conjunction with embodiments of the present disclosure. In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Client computing entities 102 may be operated by various parties. As shown in FIG. 3, the client computing entity 102 may include an antenna 312, a transmitter 304 (e.g., radio), a receiver 306 (e.g., radio), and a processing element 308 (e.g., CPLDs, microprocessors, multi-core processors, coprocessing entities, ASIPs, microcontrollers, and/or controllers) that provides signals to and receives signals from the transmitter 304 and receiver 306, correspondingly.

The signals provided to and received from the transmitter 304 and the receiver 306, correspondingly, may include signaling information/data in accordance with air interface standards of applicable wireless systems. In this regard, the client computing entity 102 may be capable of operating with one or more air interface standards, communication protocols, modulation types, and access types. More particularly, the client computing entity 102 may operate in accordance with any of a number of wireless communication standards and protocols, such as those described above with regard to the hardware locking computing entity 106. In a particular embodiment, the client computing entity 102 may operate in accordance with multiple wireless communication standards and protocols, such as UMTS, CDMA2000, 1×RTT, WCDMA, GSM, EDGE, TD-SCDMA, LTE, E-UTRAN, EVDO, HSPA, HSDPA, Wi-Fi, Wi-Fi Direct, WiMAX, UWB, IR, NFC, Bluetooth, USB, and/or the like. Similarly, the client computing entity 102 may operate in accordance with multiple wired communication standards and protocols, such as those described above with regard to the hardware locking computing entity 106 via a network interface 320.

Via these communication standards and protocols, the client computing entity 102 may communicate with various other entities using concepts such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). The client computing entity 102 may also download changes, add-ons, and updates, for instance, to its firmware, software (e.g., including executable instructions, applications, program modules), and operating system.

According to one embodiment, the client computing entity 102 may include location determining aspects, devices, modules, functionalities, and/or similar words used herein interchangeably. For example, the client computing entity 102 may include outdoor positioning aspects, such as a location module adapted to acquire, for example, latitude, longitude, altitude, geocode, course, direction, heading, speed, universal time (UTC), date, and/or various other information/data. In one embodiment, the location module may acquire data, sometimes known as ephemeris data, by identifying the number of satellites in view and the relative positions of those satellites (e.g., using global positioning systems (GPS)). The satellites may be a variety of different satellites, including Low Earth Orbit (LEO) satellite systems, Department of Defense (DOD) satellite systems, the European Union Galileo positioning systems, the Chinese Compass navigation systems, Indian Regional Navigational satellite systems, and/or the like. This data may be collected using a variety of coordinate systems, such as the DecimalDegrees (DD); Degrees, Minutes, Seconds (DMS); Universal Transverse Mercator (UTM); Universal Polar Stereographic (UPS) coordinate systems; and/or the like. Alternatively, the location information/data may be determined by triangulating the client computing entity's 102 position in connection with a variety of other systems, including cellular towers, Wi-Fi access points, and/or the like. Similarly, the client computing entity 102 may include indoor positioning aspects, such as a location module adapted to acquire, for example, latitude, longitude, altitude, geocode, course, direction, heading, speed, time, date, and/or various other information/data. Some of the indoor systems may use various position or location technologies including RFID tags, indoor beacons or transmitters, Wi-Fi access points, cellular towers, nearby computing devices (e.g., smartphones, laptops) and/or the like. For instance, such technologies may include the iBeacons, Gimbal proximity beacons, Bluetooth Low Energy (BLE) transmitters, NFC transmitters, and/or the like. These indoor positioning aspects may be used in a variety of settings to determine the location of someone or something to within inches or centimeters.

The client computing entity 102 may also comprise a user interface (that may include a display 316 coupled to a processing element 308) and/or a user input interface (coupled to a processing element 308). For example, the user interface may be a user application, browser, user interface, and/or similar words used herein interchangeably executing on and/or accessible via the client computing entity 102 to interact with and/or cause display of information/data from the hardware locking computing entity 106, as described herein. The user input interface may comprise any of a number of devices or interfaces allowing the client computing entity 102 to receive data, such as a keypad 318 (hard or soft), a touch display, voice/speech or motion interfaces, or other input device. In embodiments including a keypad 318, the keypad 318 may include (or cause display of) the conventional numeric (0-9) and related keys (#, *), and other keys used for operating the client computing entity 102 and may include a full set of alphabetic keys or set of keys that may be activated to provide a full set of alphanumeric keys. In addition to providing input, the user input interface may be used, for example, to activate or deactivate certain functions, such as screen savers and/or sleep modes.

The client computing entity 102 may also include volatile storage or memory 322 and/or non-volatile storage or memory 324, which may be embedded and/or may be removable. For example, the non-volatile memory may be ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. The volatile and non-volatile storage or memory may store databases, database instances, database management systems, data, applications, programs, program modules, scripts, source code, object code, byte code, compiled code, interpreted code, machine code, executable instructions, and/or the like to implement the functions of the client computing entity 102. As indicated, this may include a user application that is resident on the client computing entity 102 or accessible through a browser or other user interface for communicating with the hardware locking computing entity 106 and/or various other computing entities.

In another embodiment, the client computing entity 102 may include one or more components or functionality that are the same or similar to those of the hardware locking computing entity 106, as described in greater detail above. As will be recognized, these architectures and descriptions are provided for exemplary purposes only and are not limiting to the various embodiments.

In various embodiments, the client computing entity 102 may be embodied as an artificial intelligence (AI) computing entity. Accordingly, the client computing entity 102 may be configured to provide and/or receive information/data from a user via an input/output mechanism, such as a display, a camera, a speaker, a voice-activated input, and/or the like. In certain embodiments, an AI computing entity may comprise one or more predefined and executable program algorithms stored within an onboard memory storage module, and/or accessible over a network. In various embodiments, the AI computing entity may be configured to retrieve and/or execute one or more of the predefined program algorithms upon the occurrence of a predefined trigger event.

### Example System Operations

Various embodiments of the present disclosure describe steps, operations, processes, methods, functions, and/or the like for securing hardware IP against attacks, such as deobfuscation attacks. The goal of deobfuscation attacks may be to either extract a secret unlocking key of logic-locked designs or to obtain functional IP decoupled from obfuscation parts. Several deobfuscation attacks, such as oracle-guided SAT attacks, BMC-based sequential attacks, machine learning-based attacks, and removal attacks, have circumvented existing locking techniques. The most successful of these attacks may comprise SAT-based (combinational deobfuscation) and model-checker-based (sequential deobfuscation) attacks. For example, a combinational SAT attack may rely on generating distinguishing input patterns (DIPs) from a locked netlist and validating the DIPs by applying them to unlocked ICs.

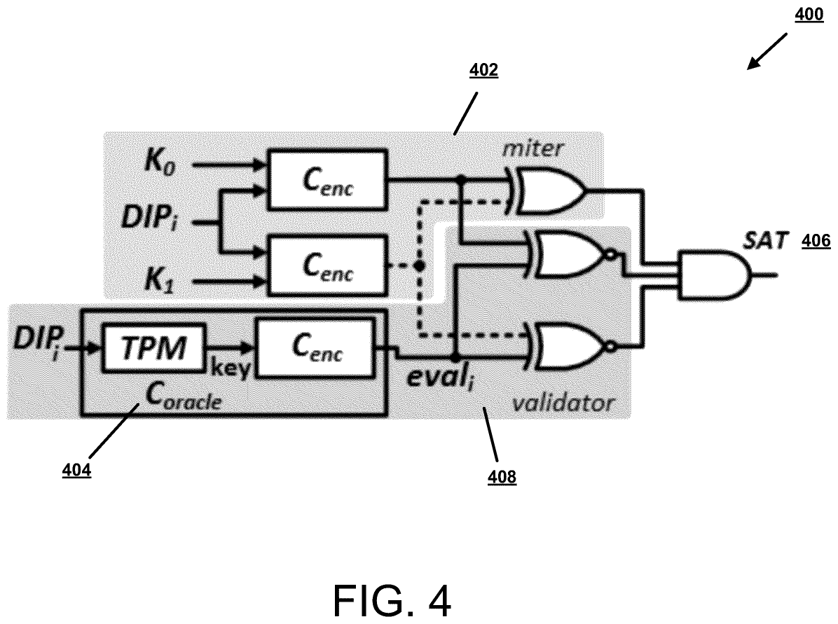

FIG. 4 depicts an example circuit 400 that may be used to perform a SAT attack. The example circuit 400 comprises a miter circuit 402 that includes two copies of a locked netlist (C_{enc}) that are fed by common primary inputs, DIPᵢ, along with key inputs K₀ and Kₗ, respectively. Output from an unlocked chip, C_{oracle} 404, that comprises a trusted platform module (TPM) and the C_{enc}, based on DIPᵢ is provided as input with to a validator circuit 408 that is configured to collect a correct response, evalᵢ that a correct key associated with C_{oracle} 404 should follow. The outputs from miter circuit 402 and validator circuit 408 may be iteratively combined for each value of DIPᵢ as a constraint to a SAT circuit 406. The SAT circuit 406 may comprise a solver configured to operate on all values of DIPᵢ to determine a correct key.

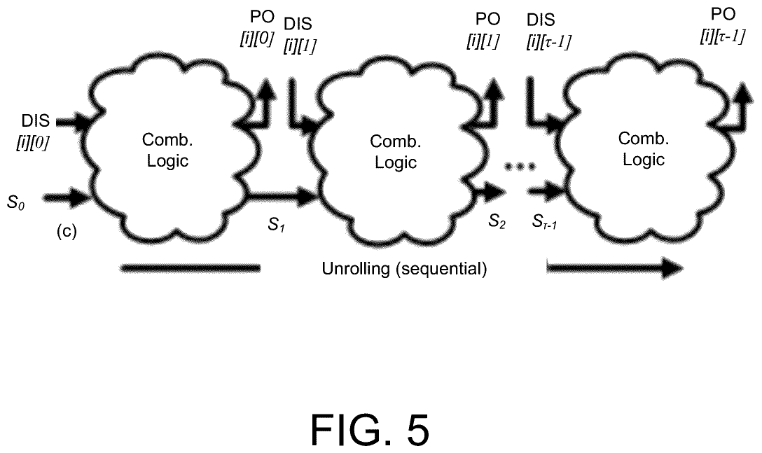

The SAT circuit 406 may utilize directed acyclic graphs (DAGs) to perform a SAT attack on a sequential design (with sequential feedbacks and cycles). An adversary may scan access or unroll a circuit to form a DAG. Where access to the design-for-testability (DFT) structure is restricted, the adversary may not split a circuit into combinational sub-circuits to apply a SAT attack but may instead use model checkers to unroll the circuit in run time, connecting state outputs of one cycle to state inputs in a next cycle, as depicted in FIG. 5. As such, miter circuits, such as miter circuit 402, may be used to find distinguishable input sequences (DISes) for different keys, and similar to SAT-based attacks, the DISes may be applied to an unlocked chip (C_{oracle} 404) to constrain a SAT circuit.

Asynchronous circuits may be provided for logic locking to obfuscate functionality of conventional sequential circuits by manipulating data flow or phase. For example, synchronous flip-flops (FFs) may be decomposed into key-controllable asynchronous latches that do not require a clock and are self-timed depending on input events. However, such decomposition and direct usage of asynchronous latches raise critical challenges during the design process. Asynchronous circuits may double the number of transistors (circuit elements) to build completion detection and meet requirement of design-for-test circuitry. Asynchronous sequential circuits may be more challenging to describe, analyze and design, specifically from scratch. Additionally, asynchronous circuits may be sensitive to relative delay between gate inputs and meeting timing criteria, such as race condition of simultaneous changes, may need to be considered meticulously, resulting in more manual labor and may require subject matter experts. Furthermore, asynchronous circuits are difficult to test and debug. Testability of asynchronous circuits require more changes within design flow and advanced EDA tools. Due to the aforementioned challenges and transformations needed in the design flow and EDA tools, industrial adaptation of asynchronous logic locking may be undesirable.

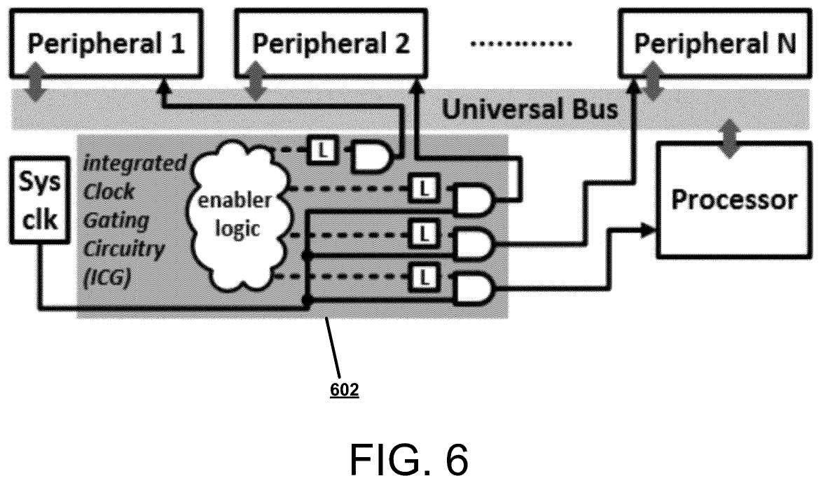

Clock gating comprises an optimization technique that may be used to reduce dynamic power consumption in circuits by preventing transitions from propagating to idle parts of a design (e.g., FFs, clock network, and logic). That is, a clock may be turned off to certain parts of a digital design when not needed to reduce power consumption. To perform clock gating, an integrated clock gating (ICG) circuit may be dedicated to a set of cells within a clock path to turn off the clock to idle blocks. Clock gating may be employed on any enabled register and may be applied by EDA tools supporting clock gating at different levels of abstraction, from gate-level to SoC-level. As depicted in FIG. 6, when a large block of logic is turned off, a clock may be gated via integrated clock gating circuitry (ICG) 602 in a clock distribution network. This approach not only turns off the registers but also the downstream combinational logic. As such, clock gating may be alternatively used to switch on and off certain parts of a circuit. Various embodiments of the present disclosure leverage clock gating for implementing a design flow friendly locking mechanism.

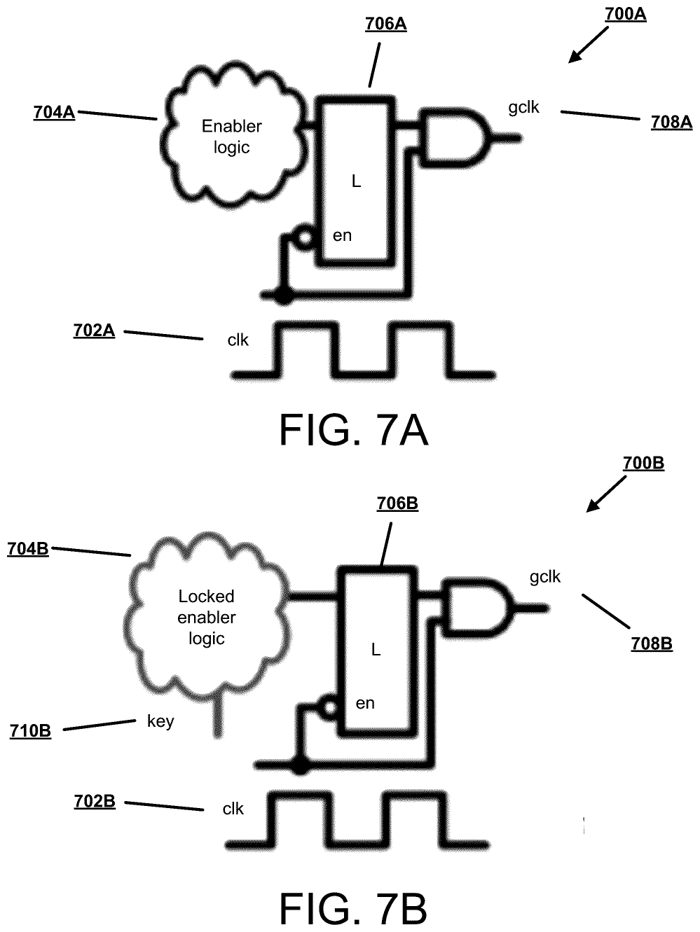

FIG. 7A depicts an example latch-based ICG cell 700A where a clock signal (clk) 702A is ANDed with an enabler logic 704A through a level-sensitive latch 706A to generate a gated output clock (gclk) 708A. ICG cells may be created in register-transfer level (RTL) designs and inserted into a circuit design by synthesis tools. ICG cells may also by manually inserted into the circuit design once a standard cell library has been defined. Either way, synthesis tools may identify modules and macros that share the same control logic and enable them when needed. Latch-based ICG cells may also be implemented as hard macros to reduce dynamic power, achieve low clock skew, remove clock glitches, and reduce area overhead.

According to various embodiments of the present disclosure, hardware designs may be locked by applying ICG cells with locked enabler logic. As depicted in FIG. 7B, an ICG cell 700B comprises an enabler logic 704B that is key gated such that the ICG cell 700B may be programmable by key inputs 710B. Gated output clock (gclk) 708B may be a function of locked enabler logic 704B, key value 710B, and the clock 702B, as defined based on gclk=ƒ(en⊕key)·clk, where ƒ(·) may represent a latch functionality. Correct functionality of a design comprising ICG cells with locked enabler logic as depicted in FIG. 7B may be restored based on the application of correct unlocking keys to each locked enabler logic of the ICG cells. Key gates associated with the locked enabler logic 704B may comprise a variety of different combinational gates (XOR/XNOR/MUX). However, to prevent glitches in the gated clock (gclk) 708B, combinational key gates (e.g., XOR) may be selected for input fan-in cone of a latch, instead of output. When a locked clock gate cell (e.g., ICG cell 700B) is unlocked, it may allow triggering of synchronous elements controlled by an associated gated clock (e.g., gclk 708B). Otherwise, the locked clock gate cell may act as a memory element (e.g., holds a previous value).

ICG cells with locked enabler logic, as disclosed herewith, may be integrated with synthesis tools, such as Synopsys Design Compiler or Cadence Genus. According to various embodiments, a method for applying ICG cells with locked enabler logic to hardware designs may comprise a combination of synthesis-based insertion and intent-based insertion. Synthesis-based insertion may comprise inserting a plurality of ICGs to a hardware design using a synthesis tool and locking one or more of the plurality of ICGs. Intent-based insertion may comprise inserting one or more intent-based decoy ICGs to resist a removal attack and to meet a key size requirement. An intent-based insertion may be based on one or more user-defined or design-specific security attributes/metrics, such as the registers dedicated for storage of secrets in crypto cores.

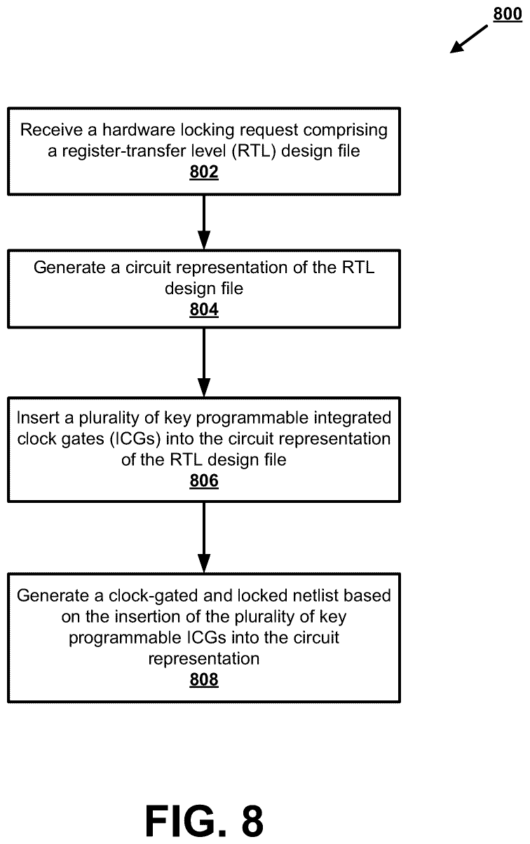

FIG. 8 is a flowchart diagram of an example process 800 for protecting an integrated circuit design according to some embodiments of the present disclosure. The process 800 includes example operations that may be performed by the hardware locking computing entity 106, and the hardware locking computing entity 106 comprises means, such as processing element 205, non-volatile memory 210, volatile memory 215, network interface 220, and/or the like, for performing the example operations.

In some embodiments, the process 800 begins at step/operation 802 when the hardware locking computing entity 106 receives a hardware locking request comprising an RTL design file. In some embodiments, the hardware locking request may comprise a request to lock an RTL design (e.g., to protect the IP of the RTL design from deobfuscation attacks). An RTL design may comprise a representation of a digital circuit described using hardware description language, such as Verilog or VHDL.

In some embodiments, at step/operation 804, the hardware locking computing entity 106 generates a circuit representation of the RTL design file. In some embodiments, generating the circuit representation may comprise analyzing and elaborating the RTL design file via synthesis. For example, the hardware locking computing entity 106 may open the RTL design file, analyze the RTL design file for errors, create one or more intermediary files based on the RTL design file, and elaborate the RTL design file into a circuit representation of the RTL design file. A circuit representation of an RTL design file may comprise a translation of the RTL design file into one or more logic elements. Analyzing the RTL design file may further comprise a multi-bit register (MBR) analysis to initiate a grouping of registers/FFs for ICG insertion into the circuit representation of the RTL design file.

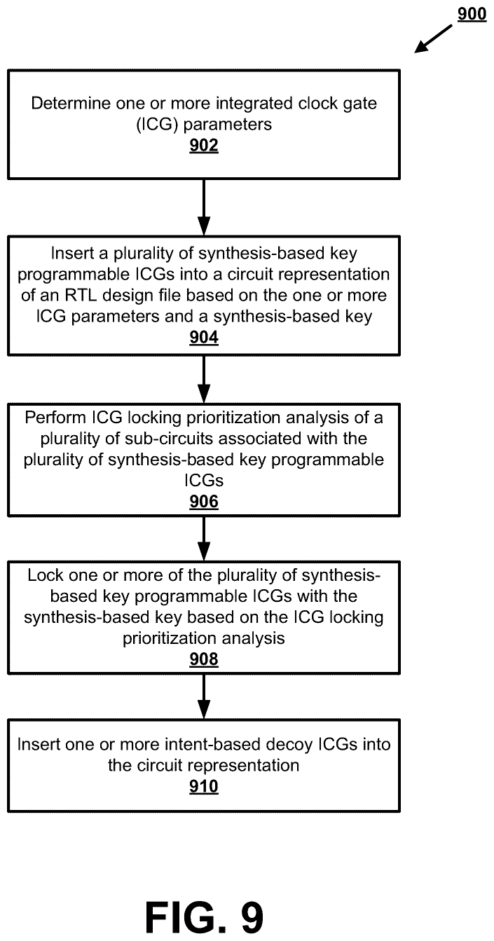

In some embodiments, at step/operation 806, the hardware locking computing entity 106 inserts a plurality of key programmable ICGs into the circuit representation of the RTL design file. As disclosed above, a key programmable ICG cell (e.g., ICG cell 700B) may comprise a ICG cell including locked enabler logic (e.g., locked enabler logic 704B), where the ICG cell may be programmed by key inputs. According to various embodiments of the present disclosure, inserting the plurality of key programmable ICGs into the circuit representation comprises inserting synthesis-based key programmable ICGs and intent-based decoy ICGs into the circuit representation, which is described in further detail with respect to the description of FIG. 9.

In some embodiments, at step/operation 808, the hardware locking computing entity 106 generates a clock gated and locked netlist based on the insertion of the plurality of key programmable ICGs into the circuit representation. Generating the clock gated and locked network may comprise performing clock gating based DFT insertion and incremental compiling.

FIG. 9 is a flowchart diagram of an example process 900 for inserting key programmable ICGs into a hardware design and locking at least a portion thereof according to some embodiments of the present disclosure. The process 900 includes example operations that may be performed by the hardware locking computing entity 106.

In some embodiments, the process 900 begins at step/operation 902 when the hardware locking computing entity 106 determines one or more ICG parameters. The one or more ICG parameters may comprise parameters that are associated with grouping of registers/FFs for ICG generation and insertion into a circuit representation. In some embodiments, determining the one or more ICG parameters comprises analyzing and elaborating, via a synthesis tool, an RTL design. Examples of ICG parameters include, but are not limited to, minimum bit width or maximum fanout of gated clock trees. In some embodiments, the one or more ICG parameters may be determined based on a 2-tuple key size comprising a synthesis-based key and an intent-based key.

In some embodiments, at step/operation 904, the hardware locking computing entity 106 inserts a plurality of synthesis-based key programmable ICGs into a circuit representation (e.g., an RTL design) based on the one or more ICG parameters and a synthesis-based key. Inserting the plurality of synthesis-based key programmable ICGs into the circuit representation may comprise clock gating logic elements within the circuit representation by attaching a ICG cell to each of one or more logic elements within the circuit representation via a synthesis tool. A logic element attached with an ICG cell may be referred to as a clock gated logic element. For example, synthesis tool-generated clock gating may comprise identifying one or more groups of logic elements, such as registers/FFs sharing common control logic, and inserting ICGs at the locations of the identified one or more groups of logic elements to control the one or more groups of logic elements. A size of the synthesis-based key may be used to determine an amount of synthesis-based key programmable ICGs to insert into the circuit representation.

In some embodiments, at step/operation 906, the hardware locking computing entity 106, performs ICG locking prioritization analysis of a plurality of sub-circuits that are associated with the plurality of synthesis-based key programmable ICGs. In certain instances, inserting the plurality of synthesis-based key programmable ICGs into the circuit representation may result in the addition of ICGs to a voluminous amount of logic elements. Although possible, it may not be very efficient to lock all of the added ICGs. As such, ICG locking prioritization analysis may be performed to prioritize certain ones of the plurality of synthesis-based key programmable ICGs inserted into the circuit representation for locking. According to various embodiments of the present disclosure, ICG locking prioritization analysis may comprise either a fanout analysis or a domination feature analysis. Fanout and domination feature analysis may be performed at different levels of abstraction, e.g., intra- or inter-IP. For instance, in SoC-level locking, both fanout and domination feature analysis may be evaluated at the SoC level, and then clock gating may be applied per IP.

Fanout analysis may comprise analyzing fanout sub-circuitry that is associated with each group of clock gated logic elements (e.g., the inserted synthesis-based key programmable ICGs). In particular, clock gated logic elements with narrower and/or shallower depth may be prioritized for locking. Logic elements with smaller fanouts may be more desirable for locking given that interacting with smaller fanouts may require a larger set of input patterns to excite errors at primary outputs. As such, a deeper form of assessment may be needed by attacks to discover the errors. Hence, keeping a fanout based precedence for locations of key-programmable ICGs may force BMC-based sequential attacks to require deeper stages for finding DISes and increase attack execution time.

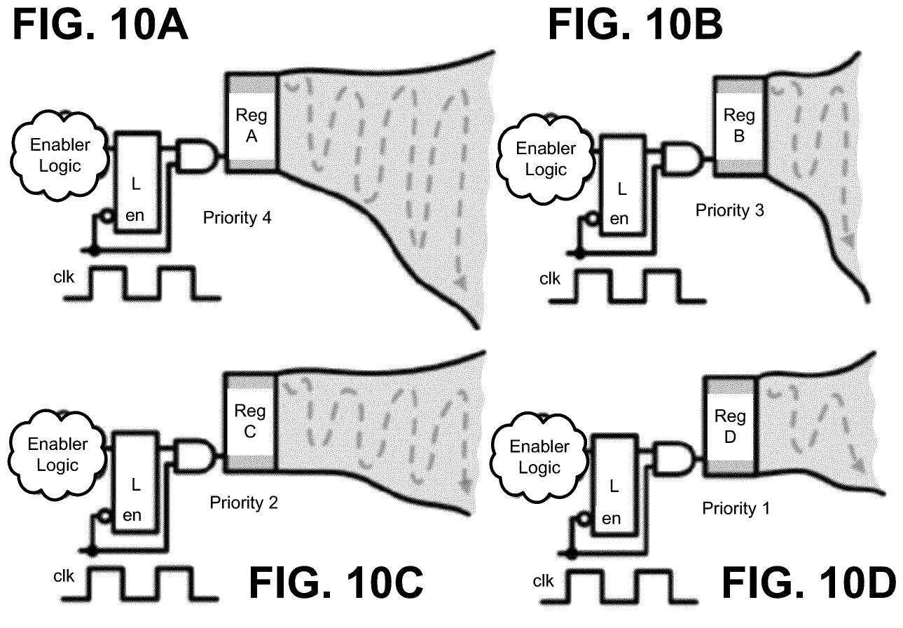

FIGS. 10A, 10B, 10C, and 10D depict example fanout analysis of fanout sub-circuitries coupled to ICGs in accordance with some embodiments of the present disclosure. The fanout of the logic depicted in FIG. 10A is larger than the fanout of the logic depicted in FIG. 10B, while the fanout of the logic depicted in FIG. 10B is larger than the fanout of the logic depicted in FIG. 10C, and the fanout of the logic depicted in FIG. 10C is larger than the fanout of the logic depicted in FIG. 10D. Based on the disclosed fanout analysis, the logic depicted in FIG. 10D comprises a shallowest and/or narrowest fanout than that of circuits depicted in FIG. 10A, FIG. 10B, and FIG. 10C, and as such, is assigned with the highest priority (priority 1) for ICG locking. Inversely, the logic depicted in FIG. 10A comprising a largest fanout than that of circuits depicted in FIG. 10B, 10C, and 10D, is assigned with the lowest priority (priority 4) for ICG locking.

Domination feature analysis may comprise selecting most significant clock gated logic elements over least significant clock gated logic elements. In some embodiments, clock gated logic elements may be analyzed based on topological order sorted based on a domination factor. The domination factor may be based on a sequence of dependencies between logic elements. According to various embodiments of the present disclosure, clock gated logic elements that are more dominant (dependent on a larger set of logic elements) may be prioritized for locking.

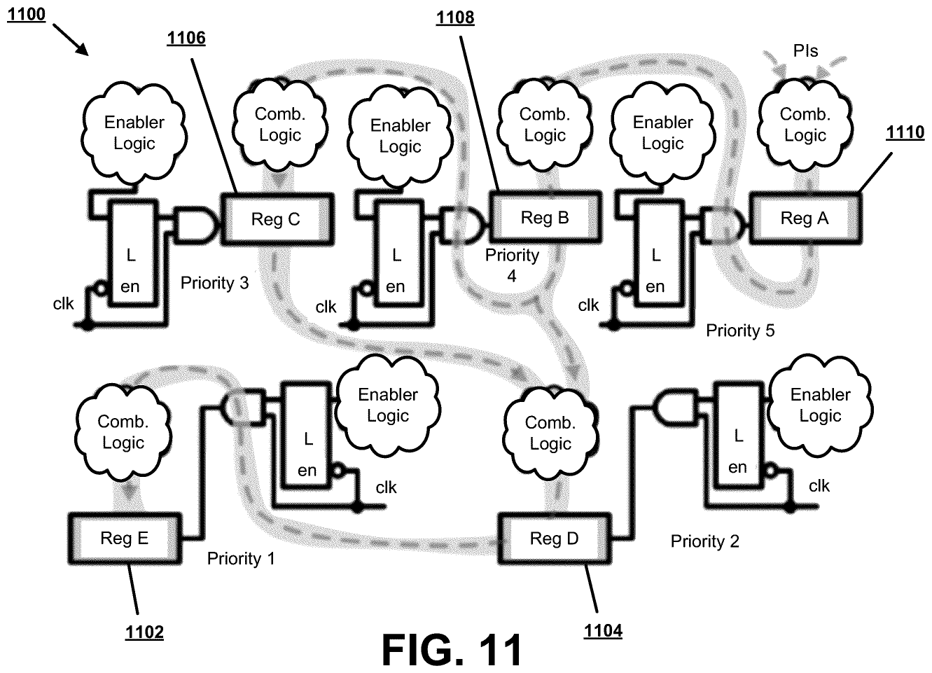

FIG. 11 depicts an example of domination feature analysis of a sub-circuit 1100 in accordance with some embodiments of the present disclosure. As depicted in FIG. 11, the output of reg_{E} 1102 is dependent on all other registers (reg_{A,B,C,D}) 1104, 1106, 1108, and 1110, and their fan-in combinational logic sub-circuits. Accordingly, reg_{E} 1102 has the most domination and may be assigned the highest priority in sub-circuit 1100 for locking its ICG cell. Similarly, based on the domination feature, reg_{D} 1104, reg_{C} 1106, reg_{B} 1108, and reg_{A} 1110, may be the next candidates after reg_{E} 1102 for locking, respectively.

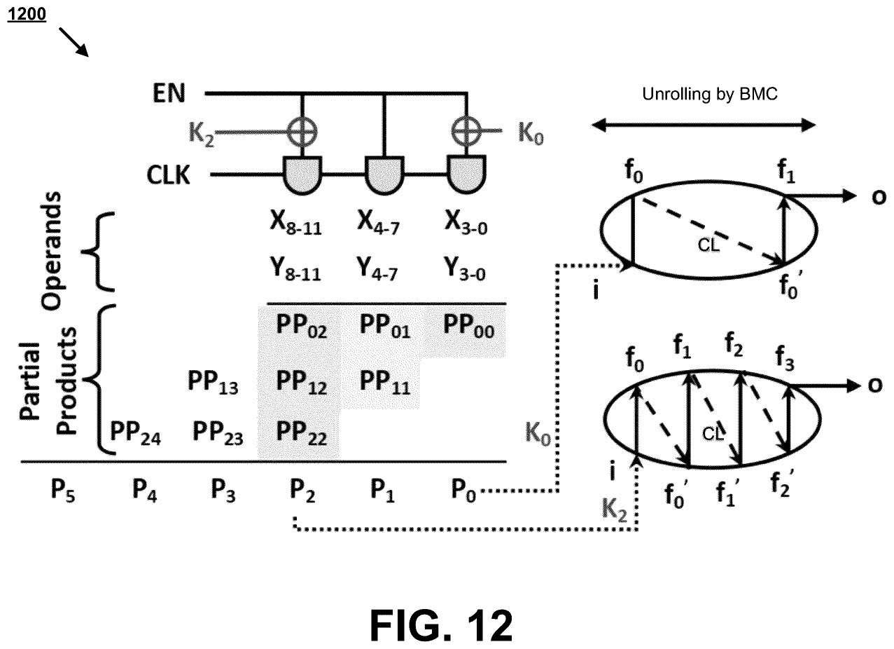

FIG. 12 depicts an example of domination feature analysis on the most significant bits (MSBs) of an arithmetic circuit 1200 in accordance with some embodiments of the present disclosure. As depicted in FIG. 12, the arithmetic circuit 1200 comprises a multiplier that is pipelined in multiple clock cycles where calculation/storage of MSBs are dependent on the least significant bits (LSBs). Assuming that all stages of a pipelined multiplier may be clock gated, the bottom-most stage(s) towards the MSBs, that are more dominant, may be prioritized for locking based on domination feature analysis. By locking MSBs (e.g., K₂) over LSBs (e.g., K₀), BMC-based attacks may require more iterations and time to retrieve a correct key.

Referring back to FIG. 9, in some embodiments, at step/operation 908, the hardware locking computing entity 106 locks one or more of the plurality of synthesis-based key programmable ICGs with the synthesis-based key based on the ICG locking prioritization analysis. Locking a synthesis-based key programmable ICG may comprise inserting key gates into enabler logics of the one or more of the plurality of synthesis-based key programmable ICGs causing the synthesis-based key programmable ICG cells to be programmable by key inputs (e.g., the synthesis-based key).

In some embodiments, at step/operation 910, the hardware locking computing entity 106 inserts one or more intent-based decoy ICGs into the circuit representation. Inserting the one or more intent-based decoy ICGs may comprise performing intent-based decoy clock gating to one or more logic elements of the circuit representation that have not already been synthesis-based clock gated (performed in step/operation 904). In some embodiments, intent-based decoy ICGs may be inserted into the circuit representation based on an intent-based key, a status of synthesis-based key programmable ICG insertion and locking, and/or user-defined or design-specific security attributes/metrics. For example, a number of synthesis-based key programmable ICGs inserted into the circuit representation by a synthesis tool may be less than required based on a size of the synthesis-based key. In this case, additional ICGs may be provided as intent-based decoy ICGs to satisfy the synthesis-based key. Furthermore, intent-based decoy ICGs may be specifically inserted to protect sensitive portions and security assets of a design. Intent-based decoy ICGs may also be inserted into the circuit representation to protect against removal attacks, as well as machine learning-based and re-synthesis-based attacks. Removal of clock gating circuitry (e.g., ICGs) tend not to affect/corrupt core functionality since clock gating typically disables idle parts of a design. Therefore, clock gate locking is vulnerable to removal attacks.

According to various embodiments of the present disclosure, intent-based decoy ICGs may comprise gating-based stripped functionality that provides controllable resilience against removal attacks and eliminates limitations that may be induced by synthesis-based clock gate locking. In some embodiments, an intent-based decoy ICG is generated by toggling the output of a sub-circuit (e.g., fan-in of a flip flop) for a selected minterm. Any non-occurring transitions to the selected minterm may be identified (e.g., using formal verification tools, such as System Verilog assertion in JasperGold). Then a key-programmable clock gating enabler logic portion of an intent-based decoy ICG that is capable of causing a corruption for the minterm may be determined based on the non-occurring transitions. The key-programmable clock gating enabler logic may be inserted at a location of the circuit representation associated with the sub-circuit such that removal or alteration of the intent-based decoy ICG causes a corruption to the sub-circuit, and yet, the insertion of the intent-based decoy ICG should not affect the original functionality of the sub-circuit.

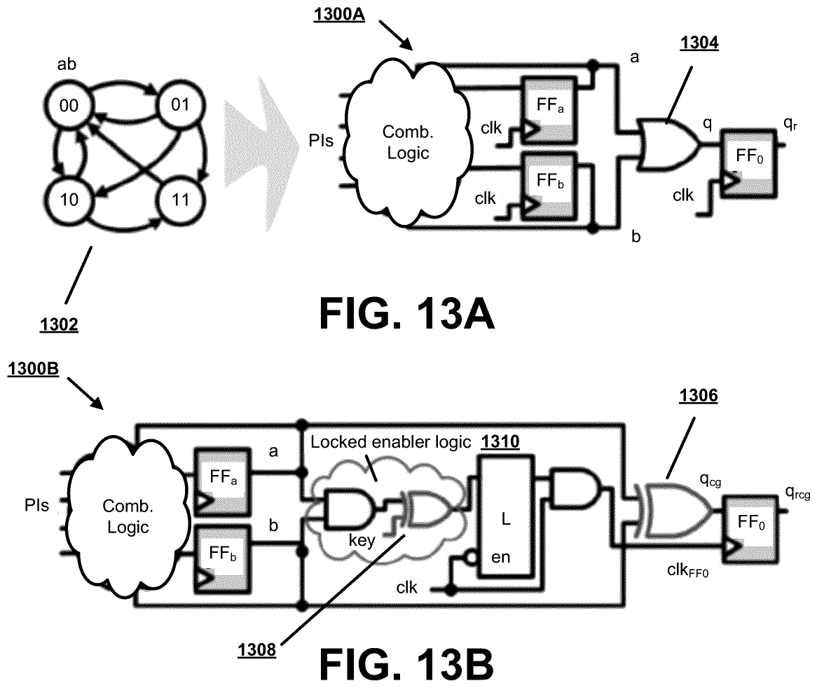

A gate-level example of how intent-based decoy clock gating may be performed according to various embodiments of the present disclosure is described with reference to FIGS. 13A, 13B, and 13C. FIG. 13A depicts a four-state FSM 1302, in which a transition ‘00’→‘11’ is a non-occurring transition, and a corresponding sub-circuit 1300A where the output of state registers FFₐ, and FF_{b} are ORed (1304) and stored in FF₀. Although ‘11’ is a valid state in the FSM 1302, since ‘00’→‘11’ is a non-occurring transition, the OR gate 1304 is replaced with an XOR gate 1306, as depicted in FIG. 13B. Circuitry related to the minterm ‘11’ (NAND 1308) is added as an enabler logic 1310 to create sub-circuit 1300B, as depicted in FIG. 13B.

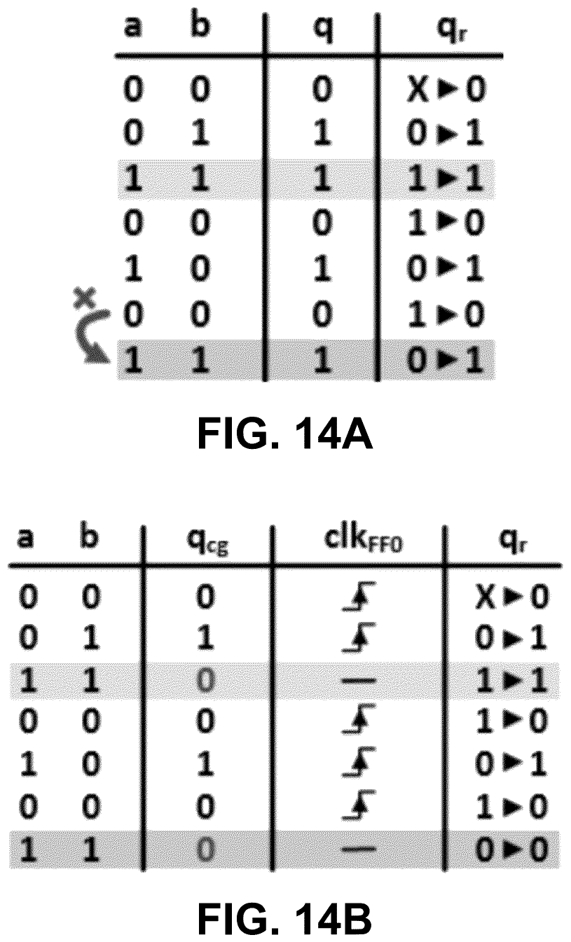

FIG. 14A depicts an example logic table of an original sub-circuit (e.g., 1300A) and FIG. 14B depicts an example logic table of the sub-circuit with an intent-based decoy ICG (e.g., 1300B) according to some embodiments of the present disclosure. The intent-based decoy ICG may be configured to keep the FF's value to preserve functionality. As depicted, if the intent-based decoy ICG is removed, corruption occurs in the transition state of the third row—the correct key is ‘1’, so, if an adversary removes the XOR key gate 1308, an AND gate remains which results in a corrupted enabler logic.

### CONCLUSION

It should be understood that the examples and embodiments described herein are for illustrative purposes only and that various modifications or changes in light thereof will be suggested to persons skilled in the art and are to be included within the spirit and purview of this application.

Many modifications and other embodiments of the present disclosure set forth herein will come to mind to one skilled in the art to which the present disclosures pertain having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claim concepts. Although specific terms are employed herein, they are used in a generic and descriptive sense only and not for purposes of limitation.

1. A method for protecting intellectual property of a hardware design, the method comprising:
receiving a hardware locking request comprising a register transfer level (RTL) design file;
generating a circuit representation of the RTL design file, the circuit representation comprising a translation of the RTL design file into one or more logic elements;
inserting a plurality of key programmable integrated clock gates (ICGs) into the circuit representation; and
generating a clock gated and locked netlist based on the insertion of the plurality of key programmable ICGs into the circuit representation.

2. The method of claim 1, wherein inserting the plurality of key programmable ICGs into the circuit representation further comprises:
determining one or more ICG parameters;
inserting a plurality of synthesis-based key programmable ICGs into the circuit representation based on the one or more ICG parameters and a synthesis-based key;
performing ICG locking prioritization analysis of a plurality of sub-circuits that are associated with the plurality of synthesis-based key programmable ICGs;
locking one or more of the plurality of synthesis-based key programmable ICGs with the synthesis-based key based on the ICG locking prioritization analysis; and
inserting one or more intent-based decoy ICGs into the circuit representation.

3. The method of claim 2, wherein the one or more ICG parameters comprise minimum bit width or maximum fanout of gated clock trees.

4. The method of claim 2 further comprising determining the one or more ICG parameters based on a 2-tuple key size comprising the synthesis-based key and an intent-based key.

5. The method of claim 2, wherein inserting the plurality of synthesis-based key programmable ICGs into the circuit representation further comprises clock gating the one or more logic elements by attaching a ICG cell to the one or more logic elements via a synthesis tool.

6. The method of claim 2, further comprising determining an amount of the plurality of synthesis-based key programmable ICGs to insert into the circuit representation based on a size of the synthesis-based key.

7. The method of claim 2, wherein the ICG locking prioritization analysis comprises a fanout analysis or a domination feature analysis.

8. The method of claim 7, wherein the fanout analysis comprises prioritizing fanout sub-circuitry based on narrowness or shallowness of depth.

9. The method of claim 7, wherein the domination feature analysis comprises selecting most significant clock gated logic elements over least significant clock gated logic elements.

10. The method of claim 2, wherein the one or more intent-based decoy ICGs comprise gating-based stripped functionality.

11. A computing system comprising memory and one or more processors communicatively coupled to the memory, the one or more processors configured to:
receive a hardware locking request comprising a register transfer level (RTL) design file;
generate a circuit representation of the RTL design file, the circuit representation comprising a translation of the RTL design file into one or more logic elements;
insert a plurality of key programmable integrated clock gates (ICGs) into the circuit representation; and
generate a clock gated and locked netlist based on the insertion of the plurality of key programmable ICGs into the circuit representation.

12. The computing system of claim 11, wherein the one or more processors are further configured to:
determine one or more ICG parameters;
insert a plurality of synthesis-based key programmable ICGs into the circuit representation based on the one or more ICG parameters and a synthesis-based key;
perform ICG locking prioritization analysis of a plurality of sub-circuits that are associated with the plurality of synthesis-based key programmable ICGs;
lock one or more of the plurality of synthesis-based key programmable ICGs with the synthesis-based key based on the ICG locking prioritization analysis; and
insert one or more intent-based decoy ICGs into the circuit representation.

13. The computing system of claim 12, wherein the one or more ICG parameters comprise minimum bit width or maximum fanout of gated clock trees.

14. The computing system of claim 12, wherein the one or more processors are further configured to determine the one or more ICG parameters based on a 2-tuple key size comprising the synthesis-based key and an intent-based key.

15. The computing system of claim 12, wherein the one or more processors are further configured to clock gate the one or more logic elements by attaching a ICG cell to the one or more logic elements via a synthesis tool.

16. The computing system of claim 12, wherein the one or more processors are further configured to determine an amount of the plurality of synthesis-based key programmable ICGs to insert into the circuit representation based on a size of the synthesis-based key.

17. The computing system of claim 12, wherein the ICG locking prioritization analysis comprises a fanout analysis or a domination feature analysis.

18. The computing system of claim 17, wherein the domination feature analysis comprises selecting most significant clock gated logic elements over least significant clock gated logic elements.

19. The computing system of claim 17, wherein the fanout analysis comprises prioritizing fanout sub-circuitry based on narrowness or shallowness of depth.

20. One or more non-transitory computer-readable storage media including instructions that, when executed by one or more processors, cause the one or more processors to:
receive a hardware locking request comprising a register transfer level (RTL) design file;
generate a circuit representation of the RTL design file, the circuit representation comprising a translation of the RTL design file into one or more logic elements;
insert a plurality of key programmable integrated clock gates (ICGs) into the circuit representation; and
generate a clock gated and locked netlist based on the insertion of the plurality of key programmable ICGs into the circuit representation.
